(19) United States
(12) Patent Application Publication
(10) Pub. No.: US 2023/0207425 A1
(43) Pub. Date: Jun. 29, 2023

(54) VAPOR CHAMBER AND SEMICONDUCTOR PACKAGE HAVING SAME MOUNTED THEREON

(71) Applicant: KANEKA CORPORATION, Osaka (JP)

(72) Inventors: Satoshi OKU, Settsu-shi (JP); Teruo MATSUTANI, Settsu-shi (JP)

(73) Assignee: KANEKA CORPORATION, Osaka (JP)

(21) Appl. No.: 18/176,210

(22) Filed: Feb. 28, 2023

Related U.S. Application Data
(63) Continuation of application No. PCT/JP2021/032236, filed on Sep. 2, 2021.

(30) Foreign Application Priority Data
Sep. 2, 2020 (JP) 2020-147802

(51) Int. Cl. H01L 23/427; H01L 21/48

(52) U.S. Cl. CPC H01L 23/427; H01L 21/4882

(57) ABSTRACT

Provided are a vapor chamber that makes it possible to inhibit a temperature rise of a semiconductor element by efficiently transport heat generated from the semiconductor element, and a semiconductor package including the vapor chamber. By using a vapor chamber including a thermal diffusion member (2) that has thermal conductivity of not less than 500 W/mK in a planar direction perpendicular to a first outer surface and/or a second outer surface of a chamber body (1) that contains a liquid material in a hermetic space therein, it is possible to inhibit a temperature rise of a semiconductor element provided on the thermal diffusion member.

### TECHNICAL FIELD

The present invention relates to a vapor chamber including a thermal diffusion member.

### BACKGROUND ART

In recent years, the performance of electronic devices such as personal computers has dramatically improved. However, there is a problem of a temperature rise caused due to heat generated from a semiconductor element such as a CPU, and therefore a semiconductor package that has excellent cooling performance is demanded. A vapor chamber may be used as an example of a means of inhibiting a temperature rise of a semiconductor package. In order to improve heat transport performance of the vapor chamber, it is necessary to smoothly proceed with evaporation and condensation of a liquid material contained inside a chamber body of the vapor chamber. In a case where a balance between evaporation and condensation is greatly disrupted, a decrease in heat transport, called “dry out”, occurs. Therefore, it is necessary to consider an effective area of an evaporation section and a condensation section.

As a vapor chamber having improved heat transport performance, for example, Patent Literature 1 indicates that a number of fins are provided inside a chamber body of a vapor chamber, and the fins are connected to an upper plate or a lower plate so as to increase a reflux volume of a liquid material, and thus a heat transport quantity is increased. Moreover, Patent Literature 2 indicates that a vapor chamber and a substrate are connected to each other via a thermally conductive part such as metal, and that heat accumulated in the vapor chamber is transferred to the substrate side.

### CITATION LIST

### Patent Literature

[Patent Literature 1]
Japanese Patent Application Publication Tokukai No. 2015-132399

[Patent Literature 2]
Japanese Patent Application Publication Tokukai No.

### SUMMARY OF INVENTION

### Technical Problem

However, the inventors of the present invention have found that there is the following problem, that is, in recent years, further improvements in performance of electronic devices have resulted in increased quantity of heat and in reduction of area of semiconductor elements, and these lead to a decrease in effective area of an evaporation section and a condensation section, and accordingly performance of a vapor chamber decreases.

An object of an aspect of the present invention is to provide a vapor chamber that makes it possible to inhibit a temperature rise of a semiconductor element by efficiently transport heat generated from the semiconductor element, and to provide a semiconductor package including the vapor chamber.

### Solution to Problem

The inventors of the present invention conducted diligent study in view of the above problem and, as a result, have found the following facts. That is, by disposing a thermal diffusion member on a surface of a chamber body of a vapor chamber, an effect is brought about in improving a substantial effective area of an evaporation section, and by increasing a heat transport quantity of the vapor chamber, it is possible to inhibit a temperature rise of a semiconductor element. On the basis of these findings, the present invention is accomplished.

That is, a vapor chamber in accordance with an aspect of the present invention relates to the following features.

(I) A vapor chamber including: a chamber body that has a hermetic space therein; a liquid material that is contained in the chamber body; and a thermal diffusion member, the chamber body having a first outer surface, a first inner surface which is a back side of the first outer surface, a second outer surface, and a second inner surface which is a back side of the second outer surface, the hermetic space being provided between the first inner surface and the second inner surface, the liquid material being contained in the hermetic space, the thermal diffusion member being provided on the first outer surface and/or the second outer surface of the chamber body, and the thermal diffusion member having thermal conductivity of not less than 500 W/mK in a planar direction perpendicular to the first outer surface or the second outer surface of the chamber body.

### Advantageous Effects of Invention

According to an aspect of the present invention, it is possible to provide a vapor chamber that makes it possible to increase a heat transport quantity. Moreover, by using the vapor chamber in accordance with an aspect of the present invention, it is possible to provide a semiconductor package that is capable of inhibiting a temperature rise of a semiconductor element.

### BRIEF DESCRIPTION OF DRAWINGS

FIG. 1 illustrates a vapor chamber in accordance with a first embodiment of the present invention.

FIG. 2 illustrates a cross section of a vapor chamber in accordance with a second embodiment of the present invention.

FIG. 3 illustrates a cross section of a vapor chamber in accordance with a third embodiment of the present invention.

FIG. 4 illustrates a cross section of a vapor chamber in accordance with a fourth embodiment of the present invention.

FIG. 5 illustrates a semiconductor package in accordance with a first embodiment in which the vapor chamber of the first embodiment is provided.

FIG. 6 illustrates a cross section of a semiconductor package in accordance with a second embodiment in which the vapor chamber of the third embodiment is provided.

### DESCRIPTION OF EMBODIMENTS

The following description will discuss aspects of the present invention. The present invention is not, however, limited to these aspects. The present invention is not limited to the configurations described below, but may be altered in various ways within the scope of the claims. The present invention also encompasses, in its technical scope, any embodiment and any working example derived by combining technical means disclosed in differing embodiments and examples. Further, it is possible to form a new technical feature by combining the technical means disclosed in the respective embodiments. All patent literatures described in this specification are incorporated herein as reference literatures. Any numerical range expressed as “A to B” herein means “not less than A and not more than B (i.e., a range from A to B which includes both A and B)” unless otherwise stated.

A vapor chamber in accordance with an aspect of the present invention includes: a chamber body (1) that has a hermetic space therein; a liquid material (11) that is contained in the chamber body; and a thermal diffusion member (2). The chamber body has a first outer surface, a first inner surface which is a back side of the first outer surface, a second outer surface, and a second inner surface which is a back side of the second outer surface. The hermetic space is provided between the first inner surface and the second inner surface, and the liquid material (11) is contained in the hermetic space. The thermal diffusion member (2) is provided on the first outer surface and/or the second outer surface of the chamber body (1). The thermal diffusion member (2) has thermal conductivity of not less than 500 W/mK in a planar direction perpendicular to the first outer surface or the second outer surface of the chamber body (1). Here, the “planar direction perpendicular to the first outer surface or the second outer surface” indicates a “planar direction of a plane perpendicular to the first outer surface or the second outer surface”. The thermal conductivity (W/mK) indicates a quantity of heat that is conducted through a plate having a size of 1 m² when there is a temperature difference of 1° C. between both surfaces of the plate having a thickness of 1 m. Such thermal conductivity in the planar direction is represented by “thermal diffusivity×specific heat×density” in the planar direction. The thermal diffusivity in the planar direction was measured by a xenon flash method using a sample which had been cut in a size of 10 mm square and using “LFA447” manufactured by NETZSCH Japan K.K. The specific heat was measured by a DSC method using 10 mg of a sample at 50° C. The density was obtained according to the following method using a sample which had been cut in a size of 10 mm square: a volume of the sample was obtained by measuring a depth, a width, and a height thereof using a micrometer manufactured by Mitutoyo Corporation, and then a weight of the sample was divided by the volume.

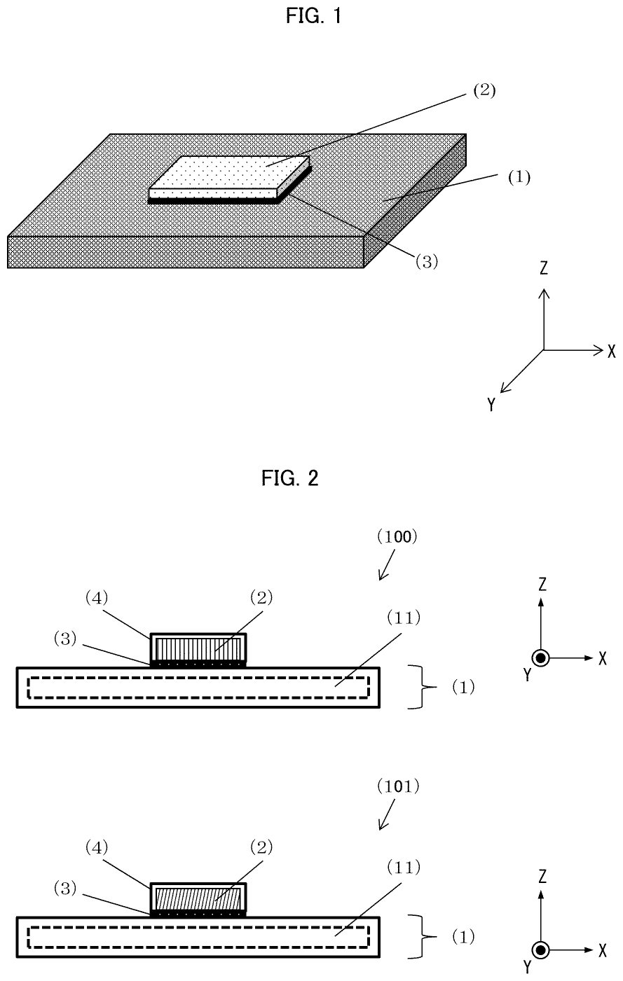

FIG. 1 illustrates a vapor chamber in accordance with a first embodiment of the present invention.

FIGS. 2 through 4 illustrate cross sections of vapor chambers in accordance with second through fourth embodiments of the present invention.

The following description will discuss members which constitute the vapor chamber in accordance with an aspect of the present invention.

### <Chamber Body (1)>

A chamber body (1) used in the vapor chamber in accordance with an aspect of the present invention has a first outer surface, a first inner surface which is a back side of the first outer surface, a second outer surface, and a second inner surface which is a back side of the second outer surface. The chamber body (1) further has a hermetic space between the first inner surface and the second inner surface. The chamber body (1) having the hermetic space is not particularly limited, provided that the chamber body (1) is made of a material and has a structure which prevent a leakage of a liquid material (11) (described later) to the outside. The material is preferably metal, and particularly preferably copper or aluminum from the viewpoint of excellent thermal conductivity. A known technique can be used as the structure. From the viewpoint of reliability of prevention of leakage of the liquid material (11) to the outside, for example, it is preferable that the structure is a hollow tubular chamber body made up of a planar plate which forms the first outer surface and the first inner surface and a bottomed tubular body which forms the second outer surface and the second inner surface. From the viewpoint of simplicity of production, the structure is further preferably made up of a square-shaped planar plate and a square-shaped bottomed tubular body. The planar plate and the bottomed tubular body are joined to each other at edges thereof by a known technique such as diffused junction, brazing, or solder so that a hollow tubular chamber body which is hermetic can be produced. It is necessary that pressure inside the chamber body is reduced with use of a vacuum pump, and a liquid material (11) is injected. Therefore, it is possible to combine two or more methods as appropriate in which, for example, parts of edges of the planar plate and the bottomed tubular body which are not an inlet are joined together by diffused junction, then a liquid material (11) is introduced, and then the inlet is brazed.

Furthermore, in order to smoothly proceed with evaporation and condensation of the liquid material (11) (described later), in the chamber body (1), all inner wall surfaces including the first inner surface and the second inner surface of the chamber body (1) preferably have, for example, a porous wick structure. Alternatively, a fine structure may be formed by etching or the like.

A size of the chamber body (1) used in the vapor chamber in accordance with an aspect of the present invention is preferably selected in view of sizes of a semiconductor element (5) and a heat sink (6) (described later). For example, the size can be, but is not particularly limited to, 100 mm×100 mm.

A total thickness of the chamber body (1) used in the vapor chamber in accordance with an aspect of the present invention is not particularly limited, and the total thickness of the chamber body (1) used can fall within a range of 0.5 mm to 10.0 mm, in view of easiness in production and handleability.

### <Liquid Material (11)>

A liquid material (11) used in the vapor chamber in accordance with an aspect of the present invention is contained inside the chamber body (1). When a temperature of the liquid material (11) reaches a temperature equal to or higher than the boiling point, the liquid material (11) evaporates on the inner wall surface of the chamber body (1), and a gas moves through the hollow part of the chamber body (1). When the temperature of the liquid material (11) reaches a temperature equal to or lower than the boiling point, the gas condenses and the liquid moves on the inner wall surface. This circulation makes it possible to semipermanently transport heat. A type of the liquid material (11) is not particularly limited, and it is possible to preferably use pure water, alcohol, ammonia, or the like. One type of the liquid can be used alone, or two or more types of the liquids can be used in combination. From the viewpoint of safety and cost, pure water is particularly preferably used.

<Thermal Diffusion Member (2)>

A thermal diffusion member (2) used in the vapor chamber in accordance with an aspect of the present invention is disposed on the first outer surface and/or the second outer surface of the chamber body (1) and has thermal conductivity of not less than 500 W/mK in a planar direction perpendicular to the first outer surface and/or the second outer surface of the chamber body (1). In a case where the thermal conductivity of the thermal diffusion member (2) is not less than 500 W/mK, heat of a semiconductor element (5) (described later) spreads in the surface while inhibiting a loss due to thermal resistance. As a result, the effective area of the evaporation section can be increased, and the heat transport quantity of the vapor chamber in accordance with an aspect of the present invention can be increased. The thermal conductivity of the thermal diffusion member (2) is preferably high, more preferably not less than 800 W/mK, and particularly preferably not less than 1000 W/mK.

<Anisotropic Graphite>

A material of the thermal diffusion member (2) used in the vapor chamber in accordance with an aspect of the present invention preferably includes anisotropic graphite, from the viewpoint of thermal conductivity. The anisotropic graphite is graphite in which a plurality of graphite layers are stacked and which has high thermal conductivity along the crystal orientation plane. In a direction perpendicular to the crystal orientation plane, the anisotropic graphite generally has low thermal conductivity. A method of producing anisotropic graphite is not particularly limited, and anisotropic graphite can be produced by cutting a graphite block. Examples of a method of cutting a graphite block include methods each employing a diamond cutter, a wire saw, machining, or the like. The wire saw is preferable, because the graphite block can be easily processed into a rectangular parallelepiped shape.

The anisotropic graphite may be surface polished or roughened, and a known technique such as file polishing, buff polishing, or blasting can be used as appropriate.

As described above, the thermal diffusion member (2) has thermal conductivity of not less than 500 W/mK in a planar direction perpendicular to the first outer surface and/or the second outer surface of the chamber body (1). As in the vapor chamber (100) illustrated in FIGS. 1 and 2, in a case where, for example, the thermal diffusion member (2) is disposed on the first outer surface such that the crystal orientation plane of the anisotropic graphite is perpendicular to the first outer surface of the chamber body (1) and is parallel to a YZ plane, the thermal diffusion member (2) has thermal conductivity of not less than 500 W/mK in the planar direction of the YZ plane. The longitudinal lines in a Z-axis direction of the thermal diffusion member (2) of the vapor chamber (100) in FIG. 2 schematically indicate crystal orientation planes of the anisotropic graphite material. For example, in a case where the thermal diffusion member (2) is disposed on the first outer surface in a state of being rotated by 90 degrees about the Z axis from the state illustrated in FIGS. 1 and 2, the crystal orientation plane is parallel to an XZ plane, and the thermal diffusion member (2) has thermal conductivity of not less than 500 W/mK in the planar direction of the XZ plane. The disposition of the thermal diffusion member (2) with respect to the first outer surface and/or the second outer surface is not limited to the above described cases. It is only necessary that the thermal diffusion member (2) is disposed on the first outer surface and/or the second outer surface such that the planar direction of the crystal orientation plane of the anisotropic graphite is parallel to a plane perpendicular to the first outer surface and/or the second outer surface.

It is possible that the crystal orientation plane of the anisotropic graphite is not parallel to the planar direction perpendicular to the first outer surface and/or the second outer surface, and may have a predetermined angle. In a case where the thermal diffusion member (2) is disposed on the first outer surface as in the vapor chamber (101) illustrated in FIG. 2, for example, the crystal orientation plane may form a predetermined angle with respect to the YZ plane. From the viewpoint of handleability of the thermal diffusion member (2), the crystal orientation plane forms an angle of preferably not more than ±10 degrees, more preferably not more than ±5 degrees, with respect to the YZ plane. The present embodiment is not limited to this case, and it is only necessary that the crystal orientation plane has an angle of preferably not more than ±10 degrees and more preferably not more than ±5 degrees with respect to a plane perpendicular to the first outer surface and/or the second outer surface. It is particularly preferable that the crystal orientation plane of the anisotropic graphite is substantially parallel to the planar direction perpendicular to the first outer surface and/or the second outer surface such that the thermal diffusion member (2) has thermal conductivity of not less than 500 W/mK in the planar direction perpendicular to the first outer surface and/or the second outer surface of the chamber body (1).

<Graphite Block>

The graphite block is not particularly limited, and it is possible to use a polymer-decomposed graphite block, a thermally-decomposed graphite block, an extrusion molded graphite block, a molded graphite block, or the like. From the viewpoint of having high thermal conductivity and excellent heat transfer performance of anisotropic graphite, a polymer-decomposed graphite block and a thermally-decomposed graphite block are preferable.

A method of producing the graphite block involves, for example, introducing a carbonaceous gas such as methane into an oven, heating the gas to approximately 2000° C. with a heater, and forming fine carbon nuclei. The formed carbon nuclei are deposited on a substrate in a layer form, and thus a thermally-decomposed graphite block can be obtained. The graphite block may be produced by stacking a plurality of polymer films each made of a polyimide resin or the like, and then subjecting the polymer films to heat treatment while pressing. Specifically, a graphite block is obtained from polymer films as follows. First, a laminate obtained by stacking a plurality of polymer films which are each a starting material is preheated to a temperature of approximately 1000° C. under reduced pressure or in an inert gas so as to be carbonized. Thus, a carbonized block is obtained. After that, the carbonized block is graphitized by heat treatment to a temperature of not less than 2000° C., preferably not less than 2800° C., while pressing under an inert gas atmosphere. This makes it possible to form a good graphite crystal structure and to obtain a graphite block having excellent heat conductivity.

Specific examples of a method of producing a graphite block include a method disclosed in International Publication No. WO 2015/129317.

<Size of Thermal Diffusion Member (2)>

The thermal diffusion member (2) used in the vapor chamber in accordance with an aspect of the present invention preferably has a thickness falling within a range of 0.5 mm to 10.0 mm. In a case where the thickness is smaller than 0.5 mm, the effective area of the evaporation section cannot be sufficiently broadened, and the heat transport quantity of the vapor chamber in accordance with an aspect of the present invention is not increased. Therefore, the effect of inhibiting a temperature rise of the semiconductor element may not be exhibited. Meanwhile, in a case where the thickness is greater than 10.0 mm, the thermal resistance of the thermal diffusion member (2) itself becomes greater. Therefore, in such a case also, the heat transport quantity of the vapor chamber in accordance with an aspect of the present invention is not increased, and the effect of inhibiting a temperature rise of the semiconductor element may not be exhibited. A lower limit of the thickness of the thermal diffusion member (2) is more preferably 0.8 mm, particularly preferably 1.0 mm, because such a thickness of the thermal diffusion member (2) makes it possible to broaden the effective area of the evaporation section and to reduce the thermal resistance of the thermal diffusion member (2). An upper limit is more preferably 5.0 mm, particularly preferably 3.0 mm.

An area of the thermal diffusion member (2) in the planar direction preferably falls within a range of 4% to 100% with respect to an area of the first outer surface and/or the second outer surface of the chamber body (1). In a case where the area is smaller than 4%, the effective area of the evaporation section cannot be sufficiently broadened, and the heat transport quantity of the vapor chamber in accordance with an aspect of the present invention is not increased. Therefore, the effect of inhibiting a temperature rise of the semiconductor element may not be exhibited. Meanwhile, even if the area is greater than 100%, an effect of increasing, according to the area, the heat transport quantity of the vapor chamber in accordance with an aspect of the present invention cannot be expected. From the viewpoint of efficiently achieving effects of increasing the heat transport quantity of the vapor chamber in accordance with an aspect of the present invention and inhibiting a temperature rise of the semiconductor element, a lower limit is more preferably 8%. An upper limit is more preferably 50%.

An actual size of the thermal diffusion member (2) is not particularly limited, provided that the area in the planar direction falls within the range of 4% to 100% with respect to the area of the first outer surface and/or the second outer surface of the chamber body (1), as described above. From the viewpoint of practical use, the size preferably falls within a range of 10 mm×10 mm to 100 mm×100 mm. If the size is smaller than 10 mm×10 mm, the effective area of the evaporation section cannot be sufficiently broadened, and it is less likely that the effect of inhibiting a temperature rise of the semiconductor element is achieved. Meanwhile, even if the size is greater than 100 mm×100 mm, it is less likely that a greater effect is achieved. From the viewpoint of efficiently achieving effects of broadening the effective area of the evaporation section and inhibiting a temperature rise of the semiconductor element, the lower limit of the thermal diffusion member (2) is more preferably 20 mm×20 mm. The upper limit is more preferably 75 mm×75 mm.

### Vapor Chamber in Accordance with First Embodiment of the Present Invention

In order to efficiently achieve the effects of broadening the effective area of the evaporation section and inhibiting a temperature rise of the semiconductor element, in a vapor chamber in accordance with a first embodiment of the present invention, a thermal diffusion member (2) and a chamber body (1) are joined together via a joining layer (3), as illustrated in FIG. 1. The joining layer (3) may contain at least one type selected from the group consisting of solder, a brazing material, diffused junction, and heat conductive grease. From the viewpoint of reducing the thermal resistance exerted in the joining layer (3) as much as possible, solder, a brazing material, and diffused junction are preferable. From the viewpoint of handleability, solder is particularly preferable. A type of solder is not particularly limited, and solder in a solid form or a paste form can be used as appropriate. The thermal diffusion member (2) may be disposed on and joined to the first outer surface and/or the second outer surface of the chamber body (1) in any manner. It is more preferable that the thermal diffusion member (2) is disposed such that the entire one surface of the thermal diffusion member (2) is joined to the chamber body (1). It is particularly preferable that the thermal diffusion member (2) is disposed in a substantially central part of the chamber body (1). The same applies hereinafter in other embodiments of the present invention.

### Vapor Chamber in Accordance with Second Embodiment of the Present Invention

As a vapor chamber in accordance with a second embodiment of the present invention, the vapor chamber may include a coating layer (4) that contains metal or ceramics on at least a part of a surface of the thermal diffusion member (2) of FIG. 1 (see FIG. 2). By providing the coating layer (4) that contains metal or ceramics on at least a part of the surface, it is possible to prevent breakage of the thermal diffusion member (2), and handleability of the vapor chamber in accordance with an aspect of the present invention is improved. It is preferable that the entire surface facing the semiconductor element is coated, and it is particularly preferable that the entire surface other than the surface facing the joining layer (3) is coated.

<Method of Forming Coating Layer (4)>

It is possible to use, as a method of forming the coating layer of the second embodiment of the present invention, a known technique such as plating, spattering, or thermal spraying, a method involving joining a plate of metal or ceramics, or the like, as appropriate. In a case where the method involving joining a plate of metal or ceramics is used, it is preferable to employ a method in which: with use of known techniques such as drawing, cutting, and bending, the plate is preprocessed into a bottomed component that is capable of coating the thermal diffusion member (2), and the bottomed component is then joined to the thermal diffusion member (2) with a metal-based brazing material. The bottomed component may have an offset part (offset region). By providing an offset part as appropriate, disposition to the chamber body (1) is stabilized. The metal-based brazing material itself has relatively high thermal conductivity. Therefore, the metal-based brazing material is unlikely to cause thermal resistance. A type of the metal-based brazing material is not particularly limited. From the viewpoint of maintenance of high heat conductivity, the metal-based brazing material preferably contains silver, copper, and/or titanium.

As a joining method in a case where a metal-based brazing material is employed, a known material and a known technique can be used. For example, in a case where active silver solder is used, joining can be achieved by: heating the active silver solder having a thickness falling within a range of 0.005 mm to 0.05 mm in any one of a vacuum environment of 1×10⁻³ Pa, an argon atmosphere, and a reducing atmosphere (such as hydrogen) and at a temperature ranging from 700° C. to 1000° C. for approximately 10 minutes to approximately 1 hour; and cooling the heated active silver solder to ordinary temperature. Furthermore, a weight may be applied during heating in order to achieve a good joining state.

A lower limit of a thickness of the coating layer (4) is preferably 0.005 mm, particularly preferably 0.01 mm. An upper limit is preferably 0.5 mm, particularly preferably 0.3 mm. In a case where the thickness is smaller than 0.005 mm, an effect of preventing breakage of the thermal diffusion member (2) is unlikely to be achieved. In a case where the thickness is greater than 0.5 mm, the coating layer (4) itself exerts thermal resistance, and the heat transport quantity of the vapor chamber may decrease. Therefore, such a thickness is not preferable.

A material of the coating layer (4) is not particularly limited, provided that the material is metal or ceramics. It is preferable to use a material that has thermal conductivity of not less than 100 W/mK, such as silver, copper, aluminum, or aluminum nitride. If a material having thermal conductivity of less than 100 W/mK is used, the heat transport quantity of the vapor chamber may decrease due to the effect of thermal resistance of the coating layer. Therefore, such a material is not preferable.

### Vapor Chamber in Accordance with Third Embodiment of the Present Invention

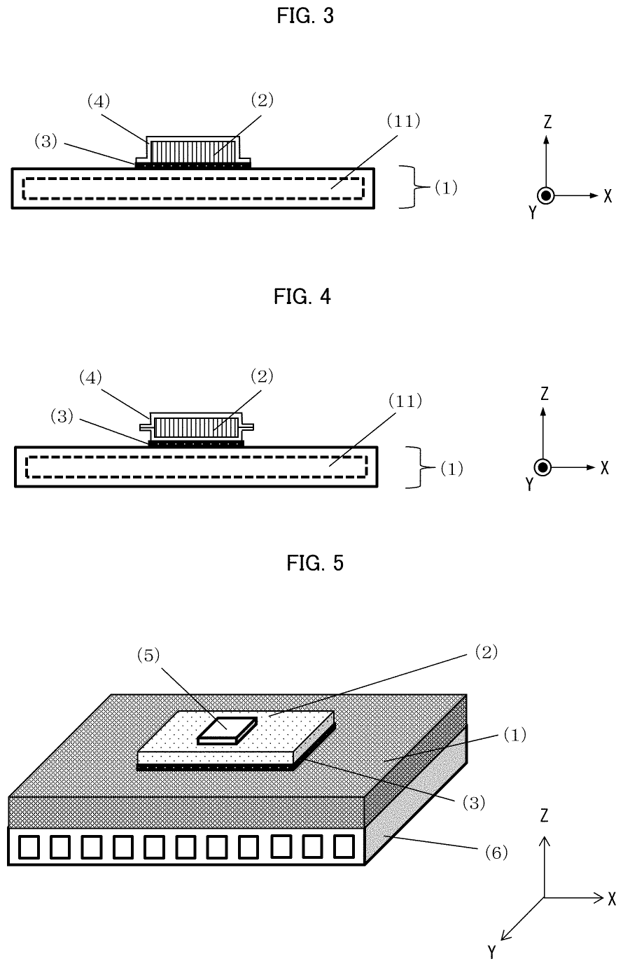

In a vapor chamber in accordance with a third embodiment of the present invention, a coating layer (4) may have an offset part provided in the planar direction at an edge of the thermal diffusion member in the planar direction (see FIG. 3). By providing such an offset part, there is an advantage that disposition to the chamber body (1) is easily stabilized. As a width of the offset part, a lower limit width is preferably 0.5 mm, and an upper limit width is preferably 5 mm. In a case where the width of the offset part is smaller than 0.5 mm, the offset part is more likely to be broken and disposition may become unstable. Meanwhile, even if the width is greater than 5 mm, there is no particular advantage, and an increase in material cost and an increase in weight may be caused. In a case where a known technique such as plating, spattering, or thermal spraying is used, a method of forming the offset part can be a method in which: a position of the offset part is determined in advance with a masking tape on the chamber body (1); a thermal diffusion member (2) is disposed and then a coating layer (4) is formed; and the masking tape is then removed. In a case where an offset part is formed by a method involving joining a plate of metal or ceramics, a method can be employed in which: known techniques such as drawing, cutting, and bending are used to preprocess the plate of metal or ceramics into a shape with which the thermal diffusion member (2) can be coated and which has an offset part; the preprocessed plate is joined to the thermal diffusion member (2) with a metal-based brazing material as with in the vapor chamber of the second embodiment of the present invention; and the thermal diffusion member (2) coated with the plate is disposed to the chamber body (1).

<Vapor Chamber in Accordance with Fourth Embodiment of the Present Invention>

In a vapor chamber in accordance with a fourth embodiment of the present invention, a coating layer may coat both surfaces of the thermal diffusion member and may have an offset part provided in the planar direction at an edge in the planar direction (see FIG. 4). By providing such an offset part, there are advantages that internal stress in the thermal diffusion member (2) can be reduced, and disposition to the chamber body (1) is easily stabilized. A width of not less than 0.5 mm is sufficient as the width of the offset part. In a case where an offset part is formed by a method involving joining a plate of metal or ceramics, a method can be employed in which: known techniques such as drawing, cutting, and bending are used to preprocess the plate of metal or ceramics into a shape with which the thermal diffusion member (2) can be coated and which has an offset part; the preprocessed plate is joined to the thermal diffusion member (2) with a metal-based brazing material as with in the vapor chamber of the second embodiment of the present invention; and the thermal diffusion member (2) coated with the plate is disposed to the chamber body (1).

<Semiconductor Package>

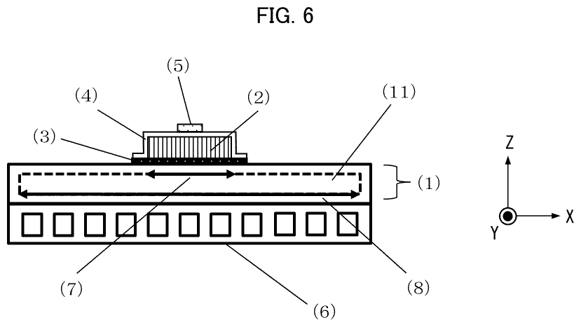

The thermal diffusion member (2) of the vapor chamber in accordance with an aspect of the present invention can be joined to a semiconductor element (5) so as to form a semiconductor package. Furthermore, it is possible to provide a semiconductor package including a heat sink (6) that is provided on a surface of the chamber body (1) of the vapor chamber in accordance with an aspect of the present invention, the surface being opposite to a side where the semiconductor element (5) is provided. A semiconductor package that includes the vapor chamber in accordance with an aspect of the present invention makes it possible to efficiently inhibit a temperature rise of the semiconductor element. FIG. 5 illustrates a semiconductor package in accordance with a first embodiment in which the vapor chamber of the first embodiment of the present invention is provided. FIG. 6 illustrates a cross section of a semiconductor package in accordance with a second embodiment in which the vapor chamber of the third embodiment of the present invention is provided. The following description will discuss members which constitute the semiconductor package including the vapor chamber of an aspect of the present invention.

<Semiconductor Element (5)>

A semiconductor element (5) used in the semiconductor package in accordance with an aspect of the present invention is not particularly limited. Examples of the semiconductor element (5) include CPU, GPU, FPGA, a transistor, a diode, a memory, and the like.

<Heat Sink (6)>

The heat sink (6) used in the semiconductor package in accordance with an aspect of the present invention is not particularly limited. It is possible to use a known heat sink such as parallel-comb-like fins, pin fins, corrugated fins, a water-cooling heat sink, a Peltier module, or the like. In a case where parallel-comb-like fins, pin fins, or corrugated fins are used, a motor fan may be used in combination to facilitate cooling.

### First Embodiment of Semiconductor Package

In order to efficiently achieve the effects of broadening the effective area of the evaporation section and inhibiting a temperature rise of the semiconductor element, a semiconductor package in accordance with a first embodiment including the vapor chamber of the first embodiment of the present invention includes a semiconductor element (5), a thermal diffusion member (2), a chamber body (1), and a heat sink (6) which are disposed in this order from the semiconductor element (5) side, as illustrated in FIG. 5. As a method of joining the thermal diffusion member (2) to the semiconductor element (5), a known method using solder, heat conductive grease, a heat conductive sheet, or the like can be employed. From the viewpoint of reducing thermal resistance as much as possible, solder is preferable. A type of solder is not particularly limited, and solder in a solid form or a paste form can be used as appropriate. As a method of joining the chamber body (1) to the heat sink (6), it is possible to use a known method using solder, a brazing material, diffused junction, heat conductive grease, a heat conductive sheet, or the like. From the viewpoint of reducing the thermal resistance as much as possible, solder, a brazing material, and diffused junction are preferable. From the viewpoint of handleability, solder is particularly preferable. A type of solder is not particularly limited, and solder in a solid form or a paste form can be used as appropriate.

### Second Embodiment of Semiconductor Package

In order to efficiently achieve the effects of broadening the effective area of an evaporation section (7) and inhibiting a temperature rise of the semiconductor element, a semiconductor package in accordance with a second embodiment including the vapor chamber of the third embodiment of the present invention includes a semiconductor element (5), a thermal diffusion member (2) provided with a coating layer (4) on the semiconductor element (5) side, a chamber body (1), and a heat sink (6) which are disposed in this order from the semiconductor element side, as illustrated in FIG. 6. A method of forming the coating layer (4) can be a method similar to those described in the second through fourth embodiments of the vapor chamber of the present invention. Methods similar to those in the first embodiment of the semiconductor package can be used as a method of joining the thermal diffusion member (2) to the semiconductor element (5), and a method of joining the chamber body (1) to the heat sink (6). In the semiconductor package including the vapor chamber of the third embodiment of the present invention, the area of the evaporation section (7) is clearly greater than the area of the semiconductor element (5), and the area of a condensation section (8) is sufficiently large, as illustrated in FIG. 6. Therefore, it is possible to efficiently inhibit a temperature rise of the semiconductor element.

### EXAMPLES

The following description will discuss Examples of the present invention.

### (Temperature Evaluation of Semiconductor Element)

A semiconductor element (10 mm×10 mm) was joined to a central part of a surface of a thermal diffusion member on a side opposite to a chamber body (in Examples 1 through 9 and Comparative Examples 2 through 4) or joined to a central part of a first outer surface of the chamber body (in Comparative Example 1), via thermally conductive grease (model number: G-775, manufactured by Shin-Etsu Chemical Co., Ltd.). A water-cooling heat sink (water temperature at 25° C.) was joined to an entire second outer surface of the chamber body via the thermally conductive grease. Thus, a semiconductor package was produced. In the semiconductor element, 100 W of heat was generated, and a temperature of the semiconductor element at that time was measured using a thermocouple. When the temperature of the semiconductor element was lower than 90° C., a temperature rise inhibitory effect was evaluated as “A”. When the temperature was not lower than 90° C. and lower than 100° C., the temperature rise inhibitory effect was evaluated as “B”. When the temperature was not lower than 100° C. and lower than 110° C., the temperature rise inhibitory effect was evaluated as “C”. When the temperature was not lower than 110° C., the temperature rise inhibitory effect was evaluated as “D”. When the evaluation was “A” or “B”, it was determined that the heat transport quantity of the vapor chamber was high, and the temperature rise of the semiconductor element in the semiconductor package could be inhibited.

### Production Example 1

A graphite block which was a raw material for anisotropic graphite A used in the thermal diffusion member was produced as follows. After 20,000 sheets of polyimide films each manufactured by Kaneka Corporation and having a size of 100 mm×100 mm×12.5 μm (thickness) were stacked, the obtained laminate was heat-treated to 2200° C. under an argon atmosphere while being pressed at a pressure of 40 kg/cm². Thus, a graphite block (90 mm×90 mm, thickness of 100 mm) was prepared. Thermal conductivity of the obtained graphite block in the direction parallel to the crystal orientation plane was 600 W/mK, and thermal conductivity in the direction perpendicular to the crystal orientation plane was 5 W/mK.

### Production Example 2

A graphite block which was a raw material for anisotropic graphite B used in the thermal diffusion member was produced as follows. After 20,000 sheets of polyimide films each manufactured by Kaneka Corporation and having a size of 100 mm×100 mm×12.5 μm (thickness) were stacked, the obtained laminate was heat-treated to 2900° C. under an argon atmosphere while being pressed at a pressure of 40 kg/cm². Thus, a graphite block (90 mm×90 mm, thickness of 100 mm) was prepared. Thermal conductivity of the obtained graphite block in the direction parallel to the crystal orientation plane was 1500 W/mK, and thermal conductivity in the direction perpendicular to the crystal orientation plane was 5 W/mK.

### Production Example 3

A chamber body was produced as follows. A chamber body having a square hollow tubular shape and having a size of 100 mm×100 mm and a thickness of 5 mm was prepared using a copper-made planar plate having a surface which forms a first outer surface and a copper-made bottomed tubular body having a surface which forms a second outer surface. A porous wick structure was provided on all inner wall surfaces, and a liquid material used was pure water.

### Example 1

The graphite block obtained in Production Example 1 was cut with a wire saw (model number: WSD-K2, manufactured by Takatori Corporation), and anisotropic graphite A having a planar size of 30 mm×30 mm and a thickness of 1.5 mm was obtained. The anisotropic graphite A had crystal orientation planes extending along the thickness direction, and had thermal conductivity of 600 W/mK. The anisotropic graphite A was disposed as a thermal diffusion member in a central part of the first outer surface of the chamber body obtained in Production Example 3 via thermally conductive grease (model number: G-775, manufactured by Shin-Etsu Chemical Co., Ltd.) to produce a vapor chamber.

A temperature evaluation of the semiconductor element was carried out using the vapor chamber, and the temperature of the semiconductor element was 95° C., and the evaluation was “B”.

### Example 2

The graphite block obtained in Production Example 2 was cut with a wire saw (model number: WSD-K2, manufactured by Takatori Corporation), and anisotropic graphite B having a planar size of 30 mm×30 mm and a thickness of 1.5 mm was obtained as a thermal diffusion member. The anisotropic graphite B had crystal orientation planes extending along the thickness direction, and had thermal conductivity of 1500 W/mK. Electrolytic plating was carried out while a masking tape (model number: 851A, manufactured by 3M) was attached to the entire one surface of the thermal diffusion member on the planar side to form a coating layer of Cu having a thickness of 0.01 mm on the surface. After that, the masking tape was removed, and thus a thermal diffusion member provided with the coating layer of Cu formed on only one surface was produced. The thermal diffusion member was disposed on a central part of the first outer surface of the chamber body obtained in Production Example 3 via thermally conductive grease (model number: G-775, manufactured by Shin-Etsu Chemical Co., Ltd.) such that a graphite-exposed surface of the thermal diffusion member faces the first outer surface of the chamber body, and thus a vapor chamber as illustrated in FIG. 2 was produced.

A temperature evaluation of the semiconductor element was carried out using the vapor chamber, and the temperature of the semiconductor element was 78° C., and the evaluation was “A”.

### Example 3

A cladding material on which active silver solder (model number: TKC-661, manufactured by TANAKA Kikinzoku Kogyo K.K.) having a thickness of 0.013 mm had been formed in advance on a copper plate having a thickness of 0.2 mm was prepared. Through drawing with use of a mold, a bottomed component was produced which had inner dimensions of 30 mm×30 mm×1.5 mm and which had an offset part with a width of 1 mm at an edge in the planar direction. In a state in which the anisotropic graphite B, which was a thermal diffusion member obtained in a manner similar to that of Example 2, was loaded in the bottomed component, the anisotropic graphite B and the bottomed component were subjected to heat treatment at 780° C. for 30 minutes under vacuum of 1×10⁻³ Pa, and were thus uniformly joined to each other. In this manner, a thermal diffusion member provided with a coating layer of Cu having a thickness of 0.2 mm and formed on only one surface was produced. The thermal diffusion member was disposed on a central part of the first outer surface of the chamber body obtained in Production Example 3 via thermally conductive grease (model number: G-775, manufactured by Shin-Etsu Chemical Co., Ltd.) such that a graphite-exposed surface of the thermal diffusion member faces the first outer surface of the chamber body, and thus a vapor chamber as illustrated in FIG. 3 was produced.

A temperature evaluation of the semiconductor element was carried out using the vapor chamber, and the temperature of the semiconductor element was 83° C., and the evaluation was “A”.

### Example 4

A vapor chamber as illustrated in FIG. 3 was produced in a manner similar to that of Example 3, except that the thickness of the anisotropic graphite B was 3.0 mm, the thickness of the copper plate was 0.3 mm, and the inner dimensions of the bottomed component were 30 mm×30 mm×3.0 mm. A temperature evaluation of the semiconductor element was carried out using the vapor chamber, and the temperature of the semiconductor element was 82° C., and the evaluation was “A”.

### Example 5

A vapor chamber as illustrated in FIG. 3 was produced in a manner similar to that of Example 3, except that the anisotropic graphite B had the planar size of 98 mm×98 mm and the thickness of 5.0 mm, and the inner dimensions of the bottomed component were 100 mm×100 mm×5.0 mm. A temperature evaluation of the semiconductor element was carried out using the vapor chamber, and the temperature of the semiconductor element was 88° C., and the evaluation was “A”.

### Example 6

An aluminum nitride block was cut and processed such that inner dimensions were 30 mm×30 mm×1.5 mm and a width of an offset part was 1 mm. Thus, a bottomed component was produced. In a state in which an active silver solder foil (model number: TKC-661, manufactured by TANAKA Kikinzoku Kogyo K.K.) having a thickness of 0.013 mm, and the anisotropic graphite B, which was a thermal diffusion member obtained in a manner similar to that of Example 2, were loaded in order in the bottomed component, the active silver solder foil, the anisotropic graphite B, and the bottomed component were subjected to heat treatment at 780° C. for 30 minutes under vacuum of 1×10⁻³ Pa, and were thus uniformly joined to each other. In this manner, a thermal diffusion member in which a coating layer of aluminum nitride having a thickness of 0.2 mm was formed on only one surface was produced. The thermal diffusion member was disposed on a central part of the first outer surface of the chamber body obtained in Production Example 3 via thermally conductive grease (model number: G-775, manufactured by Shin-Etsu Chemical Co., Ltd.) such that a graphite-exposed surface of the thermal diffusion member faces the first outer surface of the chamber body, and thus a vapor chamber as illustrated in FIG. 3 was produced.

A temperature evaluation of the semiconductor element was carried out using the vapor chamber, and the temperature of the semiconductor element was 91° C., and the evaluation was “B”.

### Example 7

A vapor chamber as illustrated in FIG. 3 was produced in a manner similar to that of Example 3, except that the anisotropic graphite B had the planar size of 20 mm×20 mm and the thickness of 1.0 mm, and the inner dimensions of the bottomed component were 20 mm×20 mm×1.0 mm. A temperature evaluation of the semiconductor element was carried out using the vapor chamber, and the temperature of the semiconductor element was 94° C., and the evaluation was “B”.

### Example 8

A cladding material on which active silver solder (model number: TKC-661, manufactured by TANAKA Kikinzoku Kogyo K.K.) having a thickness of 0.013 mm had been formed in advance on a copper plate having a thickness of 0.2 mm was prepared. Through drawing with use of a mold, a bottomed component was produced which had inner dimensions of 70 mm×70 mm×1.5 mm and which had an offset part with a width of 1 mm. In a state in which the anisotropic graphite B, which was the thermal diffusion member, was loaded between two bottomed components facing each other, the anisotropic graphite B and the bottomed components were subjected to heat treatment at 780° C. for 30 minutes under vacuum of 1×10⁻³ Pa, and were thus uniformly joined to each other. In this manner, a thermal diffusion member in which a coating layer of Cu having a thickness of 0.2 mm was formed on surfaces was produced. The thermal diffusion member was disposed on a central part of the first outer surface of the chamber body obtained in Production Example 3 via thermally conductive grease (model number: G-775, manufactured by Shin-Etsu Chemical Co., Ltd.) such that a main surface (having a size of 70 mm×70 mm) of the thermal diffusion member faces the first outer surface of the chamber body, and thus a vapor chamber as illustrated in FIG. 4 was produced.

A temperature evaluation of the semiconductor element was carried out using the vapor chamber, and the temperature of the semiconductor element was 82° C., and the evaluation was “A”.

### Example 9

A vapor chamber as illustrated in FIG. 1 was produced in a manner similar to that of Example 1, except that the anisotropic graphite B was used as a thermal diffusion member.

A temperature evaluation of the semiconductor element was carried out using the vapor chamber, and the temperature of the semiconductor element was 77° C., and the evaluation was “A”.

### Comparative Example 1

A temperature evaluation of the semiconductor element was carried out using only the chamber body obtained in Production Example 3 as the vapor chamber without providing a thermal diffusion member. As a result, the temperature of the semiconductor element was 115° C., and the evaluation was “D”.

### Comparative Example 2

A vapor chamber as illustrated in FIG. 1 was produced in a manner similar to that of Example 1, except that pure copper was used as a thermal diffusion member.

A temperature evaluation of the semiconductor element was carried out using the vapor chamber, and the temperature of the semiconductor element was 103° C., and the evaluation was “C”.

### Comparative Example 3

A vapor chamber as illustrated in FIG. 1 was produced in a manner similar to that of Comparative Example 2, except that a thermal diffusion member having a planar size of 100 mm×100 mm was used.

A temperature evaluation of the semiconductor element was carried out using the vapor chamber, and the temperature of the semiconductor element was 100° C., and the evaluation was “C”.

### Comparative Example 4

A vapor chamber as illustrated in FIG. 1 was produced in a manner similar to that of Comparative Example 3, except that a thermal diffusion member having a thickness of 5.0 mm was used.

A temperature evaluation of the semiconductor element was carried out using the vapor chamber, and the temperature of the semiconductor element was 110° C., and the evaluation was “D”.

Table 1 below indicates the compositions and evaluation results of Examples and Comparative Examples. From Table 1, it is clear that the vapor chambers in each of which the thermal diffusion member having thermal conductivity of not less than 500 W/mK is disposed are effective in inhibiting a temperature rise of the semiconductor elements.

TABLE 1

| | | Thermal diffusion member | | | | Semiconductor package | |
|---|---|---|---|---|---|---|---|
| | | Size, | | Thermal | | Temperature of | Inhibition of |
| | Size and thickness | thickness | | conductivity | | semiconductor | temperature |
| | of housing (mm) | (mm) | Material | (W/mK) | Coating layer | element (° C.) | rise |
| Example 1 | 100 × 100 × 5 | 30 × 30 × 1.5 | Anisotropic graphite A | 600 | None | 95 | B |
| Example 2 | 100 × 100 × 5 | 30 × 30 × 1.5 | Anisotropic graphite B | 1500 | Copper 0.01 mm | 78 | A |
| Example 3 | 100 × 100 × 5 | 30 × 30 × 1.5 | Anisotropic graphite B | 1500 | Copper 0.2 mm | 83 | A |
| Example 4 | 100 × 100 × 5 | 30 × 30 × 3.0 | Anisotropic graphite B | 1500 | Copper 0.3 mm | 82 | A |
| Example 5 | 100 × 100 × 5 | 98 × 98 × 5.0 | Anisotropic graphite B | 1500 | Copper 0.2 mm | 88 | A |
| Example 6 | 100 × 100 × 5 | 30 × 30 × 1.5 | Anisotropic graphite B | 1500 | Aluminum nitride 0.2 | 91 | B |
| | | | | | mm | | |
| Example 7 | 100 × 100 × 5 | 20 × 20 × 1.0 | Anisotropic graphite B | 1500 | Copper 0.2 mm | 94 | B |
| Example 8 | 100 × 100 × 5 | 70 × 70 × 3.0 | Anisotropic graphite B | 1500 | Copper 0.2 mm | 82 | A |
| Example 9 | 100 × 100 × 5 | 30 × 30 × 1.5 | Anisotropic graphite B | 1500 | None | 77 | A |
| Comparative | 100 × 100 × 5 | None | — | — | — | 115 | D |
| Example 1 | | | | | | | |
| Comparative | 100 × 100 × 5 | 30 × 30 × 1.5 | Copper | 390 | None | 103 | C |
| Example 2 | | | | | | | |
| Comparative | 100 × 100 × 5 | 100 × 100 × 1.5 | Copper | 390 | None | 100 | C |
| Example 3 | | | | | | | |
| Comparative | 100 × 100 × 5 | 100 × 100 × 5.0 | Copper | 390 | None | 110 | D |
| Example 4 | | | | | | | |

The vapor chamber in accordance with an aspect of the present invention relates to the following features.

(I) A vapor chamber including: a chamber body that has a hermetic space therein; a liquid material that is contained in the chamber body; and a thermal diffusion member, the chamber body having a first outer surface, a first inner surface which is a back side of the first outer surface, a second outer surface, and a second inner surface which is a back side of the second outer surface, the hermetic space being provided between the first inner surface and the second inner surface, the liquid material being contained in the hermetic space, the thermal diffusion member being provided on the first outer surface and/or the second outer surface of the chamber body, and the thermal diffusion member having thermal conductivity of not less than 500 W/mK in a planar direction perpendicular to the first outer surface or the second outer surface of the chamber body.

(II) The vapor chamber described in (I), in which the thermal diffusion member contains anisotropic graphite.

(III) The vapor chamber described in (II), in which: a crystal orientation plane of the anisotropic graphite forms an angle within ±10 degrees with respect to a plane perpendicular to the first outer surface or the second outer surface.

(IV) The vapor chamber described in any one of (I) through (III), in which the chamber body is made of metal.

(V) The vapor chamber described in any one of (I) through (IV), in which: the thermal diffusion member is joined to the chamber body via a joining layer; and the joining layer contains at least one type selected from the group consisting of solder, a brazing material, diffused junction, and heat conductive grease.

(VI) The vapor chamber described in any one of (I) through (V), further including a coating layer that is provided on at least a part of a surface of the thermal diffusion member, the coating layer containing metal or ceramics.

(VII) The vapor chamber described in (VI), in which a thickness of the coating layer is 0.005 mm to 0.5 mm.

(VIII) The vapor chamber described in (VI) or (VII), in which: the coating layer has an offset region at an edge of the thermal diffusion member in a planar direction of the thermal diffusion member, the offset region having a width of not less than 0.5 mm in the planar direction.

(IX) The vapor chamber described in any one of (I) through (VIII), in which a thickness of the thermal diffusion member is 0.5 mm to 10.0 mm.

(X) The vapor chamber as set forth in any one of (I) through (IX), in which: an area of the thermal diffusion member in the planar direction is 4% to 100% of an area of the first outer surface or the second outer surface of the chamber body.

(XI) A semiconductor package, including: a semiconductor element; and a vapor chamber described in any one of (I) through (X), the thermal diffusion member being joined to the semiconductor element.

(XII) The semiconductor package described in (XI), further including a heat sink that is provided on a surface of the chamber body opposite to a surface on which the thermal diffusion member is provided.

### INDUSTRIAL APPLICABILITY

The vapor chamber in accordance with an aspect of the present invention is suitable for providing a semiconductor package that is capable of inhibiting a temperature rise of a semiconductor element.

### REFERENCE SIGNS LIST

(1) Chamber body
(11) Liquid material
(2) Thermal diffusion member
(3) Joining layer
(4) Coating layer
(5) Semiconductor element
(6) Heat sink
(7) Evaporation section
(8) Condensation section

1. A vapor chamber comprising:
a chamber body that has a hermetic space therein which is configured to contain a liquid material therein; and
a thermal diffusion member,
the chamber body having a first outer surface, a first inner surface which is a back side of the first outer surface, a second outer surface, and a second inner surface which is a back side of the second outer surface,
the hermetic space being between the first inner surface and the second inner surface,
the thermal diffusion member being on the first outer surface and/or the second outer surface of the chamber body,
the thermal diffusion member having thermal conductivity of not less than 500 W/mK in a planar direction perpendicular to the first outer surface or the second outer surface of the chamber body, and
the thermal diffusion member containing anisotropic graphite.

2. The vapor chamber as set forth in claim 1, wherein:
a crystal orientation plane of the anisotropic graphite forms an angle within ±10 degrees with respect to a plane perpendicular to the first outer surface or the second outer surface.

3. The vapor chamber as set forth in claim 1, wherein the chamber body is made of metal.

4. The vapor chamber as set forth in claim 1, wherein:
the thermal diffusion member is joined to the chamber body via a joining layer; and
the joining layer contains at least one type selected from the group consisting of solder, a brazing material, diffused junction, and heat conductive grease.

5. The vapor chamber as set forth in claim 1, further comprising:
a coating layer that is on at least a part of a surface of the thermal diffusion member, the coating layer containing metal or ceramics.

6. The vapor chamber as set forth in claim 5, wherein a thickness of the coating layer is 0.005 mm to 0.5 mm.

7. The vapor chamber as set forth in claim 5, wherein:
the coating layer has an offset region at an edge of the thermal diffusion member in a planar direction of the thermal diffusion member, the offset region having a width of not less than 0.5 mm in the planar direction.

8. The vapor chamber as set forth in claim 1, wherein a thickness of the thermal diffusion member is 0.5 mm to 10.0 mm.

9. The vapor chamber as set forth in claim 1, wherein:
an area of the thermal diffusion member in the planar direction is 4% to 100% of an area of the first outer surface or the second outer surface of the chamber body.

10. A semiconductor package, comprising:
a semiconductor element; and
a vapor chamber recited in claim 1,
the thermal diffusion member being joined to the semiconductor element.

11. The semiconductor package as set forth in claim 10, further comprising:
a heat sink that is on a surface of the chamber body opposite to a surface on which the thermal diffusion member is present.

12. The vapor chamber as set forth in claim 3, wherein the chamber body is made of metal.

13. The vapor chamber as set forth in claim 7, wherein:
the coating layer has an offset region at an edge of the thermal diffusion member in a planar direction of the thermal diffusion member, the offset region having a width of not less than 0.5 mm in the planar direction.
